(19) United States
(12) Patent Application Publication
(10) Pub. No.: US 2005/0141642 A1
(43) Pub. Date: Jun. 30, 2005

(54) Transformer, transforming apparatus, transforming method and machine readable medium storing thereon program

(75) Inventor: Koji Asami, Tokyo (JP)

Correspondence Address: OSHA LIANG L.L.P., 1221 MCKINNEY STREET, SUITE 2800, HOUSTON, TX, 77010, US

(73) Assignee: Advantest Corporation, Tokyo (JP)

(21) Appl. No.: 11/023,317

(22) Filed: Dec. 27, 2004

Related U.S. Application Data
(63) Continuation of application No. PCT/JP03/08022, filed on Jun. 25, 2003.

(30) Foreign Application Priority Data
Jun. 28, 2002 (JP) 2002-190912

(51) Int. Cl. H03K 9/00

(52) U.S. Cl. 375/316

(57) ABSTRACT

A detector for detecting a signal to be measured, which is made to discrete with a predetermined discrete frequency, is provided, wherein the detector includes an analysis signal transformer for eliminating aliasing components of the signal to be measured, which are generated due to the discreteness, by transforming the signal to be measured into an analysis signal of which the discrete frequency is lower than that of the signal to be measured, and a base band signal generating unit for frequency-shifting the analysis signal and generating a complex base band signal of the signal to be measured.

The present patent application is a continuation application of PCT/JP2003/008022 filed on Jun. 25, 2003 which claims priority from Japanese Patent Application No. 2002-190912 filed on Jun. 28, 2002, the contents of which are incorporated herein by reference.

### BACKGROUND OF THE INVENTION

1. Field of the Invention

The present invention relates to a detector for detecting a signal to be measured, a testing apparatus for testing an electronic device, a testing method for testing an electronic device and a machine readable medium storing thereon a program for operating the testing apparatus. More particularly, the present invention relates to a detector and the like for detecting a signal to be measured which is made to discrete. In addition, the present application claims the benefit of, and priority to, Japanese patent application No. 2002-190912 filed on Jun. 28, 2002, the entire contents of which are incorporated herein by reference for all purposes.

2. Description of the Related Art

So far, for example, in a field of communication, a signal is modulated by a carrier signal having a desired frequency and then transmitted. A receiver receives the modulated signal and demodulates it based on the frequency of the carrier signal.

In order to test electronic devices used for this kind of modulation and demodulation of a signal, there have been testing apparatus for demodulating the modulated signal and testing the electronic apparatus based on the demodulated signal. Conventional testing apparatus have decided acceptability of electronic devices and detectors which have been used for modulation, by making a modulated signal discrete with a predetermined discrete frequency, detecting the discrete signal by the detector, and analyzing the detected signal.

However, due to making the modulated signal discrete, the discrete signal has aliasing components which have been generated with correspondent to the discrete frequency, and thus, it has been difficult to demodulate the modulated signal precisely. For this reason, it has been difficult to precisely decide acceptability of the electronic devices.

Further, in case of detecting the modulated signal by a detector, aliasing components has been generated by the detection because the modulated signal is an actual signal. For conventional testing apparatus, band pass filters or low pass filters have been widely used to remove these kinds of aliasing signal components. However, in order to remove only the aliasing signal components, it has been required to use band pass filters or low pass filters having sharp cut-off characteristics, which are difficult to be embodied. Furthermore, if the frequency band of signal components, which are to be detected and that of aliasing signal components are overlapped, it is difficult to remove only the aliasing signal components.

Accordingly, it is an object of the present invention to provide a detector, a testing apparatus, a testing method and a machine readable medium storing thereon a program, which are capable of overcoming the above drawbacks accompanying the conventional art. The above object can be achieved by combinations described in the independent claims. The dependent claims define further advantageous and exemplary combinations of the present invention.

### SUMMARY OF INVENTION

In order to solve the problems above, according to a first aspect of the present invention, a detector for detecting a signal to be measured, which is made to discrete with a predetermined discrete frequency, is provided, wherein the detector includes an analysis signal transformer for eliminating aliasing components of the signal to be measured, which are generated due to the discreteness, by transforming the signal to be measured into an analysis signal of which the discrete frequency is lower than that of the signal to be measured, and a base band signal generating unit for frequency-shifting the analysis signal and generating a complex base band signal of the signal to be measured.

The analysis signal transformer may include a decimation filter, which extracts complex data from discrete complex data of the analysis signal at every predetermined data number and provides the base band signal generating unit with the extracted complex data.

The analysis signal transformer may output the signal to be measured as a real number part of the analysis signal and output the Hilbert transformed signal of the signal to be measured as an imaginary number part of the analysis signal. Further, the analysis signal transformer may generate the analysis signal which is made to discrete by a Hilbert transform filter.

The analysis signal transformer may include a Hilbert transform filter for generating the analysis signal which is made to discrete, and the Hilbert transform filter may include a plurality of cascade-connected delay elements which receive the discrete data of the signal to be measured, each of which delays the data by a delay quantity corresponding to the discrete period of the signal to be measured and outputs the delayed data sequentially; a plurality of decimation filters for extracting data from the data which are output from the plurality of delay elements at every predetermined data number; a plurality of multipliers, each of which multiplies the extracted data from each of the plurality of decimation filters by a predetermined coefficient; and an adding unit for calculating a total sum of the data which are synchronously output from the decimation filters and multiplied by the predetermined coefficient by the plurality of multipliers and generating an imaginary number part of the analysis signal.

Further, the analysis signal transformer may include a Hilbert transform filter for generating the analysis signal which is made to discrete, the Hilbert transform filter may include a plurality of cascade-connected delay elements which receive the discrete data of the signal to be measured, each of which delays the data by a delay quantity corresponding to the discrete period of the signal to be measured and outputs the delayed data sequentially; a plurality of decimation filters for extracting data from the data which are output from the plurality of delay elements at every predetermined data number; an adding unit for calculating a sum of the extracted data for every two corresponding decimation filters; a multiplying unit for multiplying each of the sums of the data which are calculated by the adding unit by a predetermined coefficient; and an adder for calculating a total sum of the data which are synchronously output from the decimation filters and multiplied by the predetermined coefficient by the multiplying unit.

The analysis signal transformer may include a Fourier transforming unit for applying discrete Fourier transform to the signal to be measured; a band limiter for generating a band-limit signal by eliminating frequency components of which the frequency is higher than about half of the discrete frequency from the frequency components of the signal to be measured which is discrete Fourier transformed; and an inverse Fourier transforming unit for generating the analysis signal by applying inverse Fourier transform to the band-limit signal.

The analysis signal transformer may further include a decimation filter which extracts complex data of the discrete base-limit signal at every predetermined data number and provides the inverse Fourier transforming unit with the extracted complex data.

The signal to be measured may be a signal which is frequency-shifted by a carrier signal having a predetermined frequency, and the base band signal generating unit may phase-shift the frequency of the analysis signal on the basis of the predetermined frequency.

According to a second aspect of the present invention, a detector for detecting a signal to be measured, which is made to discrete with a predetermined discrete frequency, is provided, wherein the detector includes an analysis signal transformer for eliminating aliasing components of the signal to be measured, which are generated due to the discreteness, by transforming the signal to be measured into an analysis signal; a base band signal generating unit for frequency-shifting the analysis signal and generating a complex base band signal of the signal to be measured; and a decimation filter for receiving the complex base band signal, extracting the complex data from the complex data of the complex base band signal at every predetermined data number, and generating the complex base band signal of which the discrete frequency is lower than that of the signal to be measured.

The decimation filter may correct the value of the amplitude of each complex data of the complex base band signal on the basis of a predetermined value. Further, the decimation filter may correct the phase of the complex base band signal on the basis of the ratio of I-phase component to Q-phase component of the complex base band signal.

According to a third aspect of the present invention, a detector for detecting a signal to be measured, which is made to discrete with a predetermined discrete frequency and frequency-shifted by a carrier signal having a predetermined frequency, is provided, wherein the detector includes a Fourier transforming unit for applying Fourier transform to the signal to be measured; a band limiter for generating a band-limit signal by eliminating frequency components of which the frequency is higher than about half of the discrete frequency from the frequency components of the signal to be measured which is Fourier transformed; a decimation filter for extracting and outputting the band-limit signal at every predetermined data number; a frequency-shifter for shifting the band-limit signal, which the decimation filter outputs, on a frequency axis on the basis of the carrier signal; and an inverse Fourier transforming unit for applying inverse Fourier transform to the band-limit signal which is frequency-shifted by the frequency shifter.

According to a fourth aspect of the present invention, a testing apparatus, which decides acceptability of an electronic device on the basis of a modulated signal output from the electronic device, is provided, wherein the testing apparatus includes an AD converter for making the modulated signal discrete and converting into a signal to be measured; an analysis signal transformer for eliminating aliasing components of the signal to be measured, which are generated due to the discreteness, by transforming the signal to be measured into an analysis signal of which the discrete frequency is lower than that of the signal to be measured; a base band signal generating unit for phase-shifting the analysis signal and generating a complex base band signal of the signal to be measure; and an analyzing unit for deciding acceptability of the electronic device based on the complex base band signal.

According to a fifth aspect of the present invention, a testing method, which decides acceptability of an electronic device on the basis of a modulated signal output from the electronic device, is provided, wherein the testing method includes an AD converting step of making the modulated signal discrete and converting into a signal to be measured; an analysis signal transforming step of eliminating aliasing components of the signal to be measured, which are generated due to the discreteness, by transforming the signal to be measured into an analysis signal of which the discrete frequency is lower than that of the signal to be measured; a base band signal generating step of phase-shifting the analysis signal and generating a complex base band signal of the signal to be measure; and an analyzing step of deciding acceptability of the electronic device based on the complex base band signal.

According to a sixth aspect of the present invention, a machine readable medium storing thereon a program for making a computer perform functions as a testing apparatus, which decides acceptability of an electronic device on the basis of a modulated signal output from the electronic device, is provided, wherein the program makes the computer perform functions as an AD converter for making the modulated signal discrete and converting into a signal to be measured; an analysis signal transformer for eliminating aliasing components of the signal to be measured, which are generated due to the discreteness, by transforming the signal to be measured into an analysis signal of which the discrete frequency is lower than that of the signal to be measured; a base band signal generating unit for phase-shifting the analysis signal and generating a complex base band signal of the signal to be measure; and an analyzing unit for deciding acceptability of the electronic device based on the complex base band signal.

The summary of the invention does not necessarily describe all necessary features of the present invention. The present invention may also be a sub-combination of the features described above.

### BRIEF DESCRIPTION OF THE DRAWINGS

FIG. 1 shows an example of the configuration of a testing apparatus 100 according to an embodiment of the present invention.

FIG. 2A shows an example of a frequency component of the signal to be detected which an AD converter 20 makes discrete.

FIG. 2B shows an example of a frequency component in case of detecting an actual signal.

FIG. 2C shows an example of a frequency component of a signal which the testing apparatus 100 of the present embodiment detects

FIG. 2D shows an example of a frequency component of a signal which the testing apparatus 100 of the present embodiment detects, in case of down-sampling an analysis signal.

FIG. 3A shows an example of the configuration of the analysis signal transformer 30.

FIG. 3B shows another example of the configuration of the analysis signal transformer 30

FIG. 3C shows another example of the analysis signal transformer 30 which has different configuration.

FIG. 4 shows an example of the configuration of a Hilbert transform filter 60.

FIG. 5 shows another example of the configuration of the testing apparatus 100.

FIG. 6 explains phase error correction of a complex base band signal for a decimation filter 70.

FIG. 7A shows another example of the configuration of the Hilbert transform filter 60.

FIG. 7B shows another example of the Hilbert transform filter 60 which has different configuration.

FIG. 8A shows another example of the configuration of the analysis signal transformer 30 which uses Fourier transform.

FIG. 8B shows another example of the analysis signal transformer 30 which has different configuration.

FIG. 9 is a flowchart to explain an example of a testing method according to an embodiment of the present invention.

FIG. 10 shows an example of the hardware configuration of a computer 300 according to an embodiment of the present invention.

### DETAILED DESCRIPTION OF THE INVENTION

The invention will now be described based on the preferred embodiments, which do not intend to limit the scope of the present invention, but exemplify the invention. All of the features and the combinations thereof described in the embodiment are not necessarily essential to the invention.

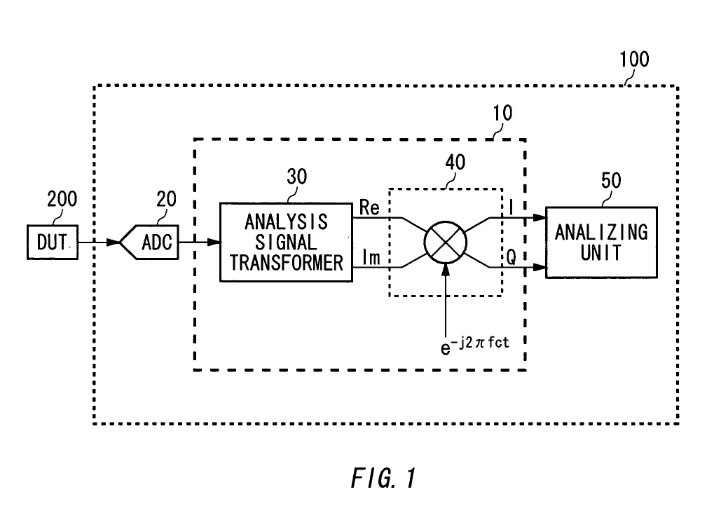

FIG. 1 shows an example of the configuration of a testing apparatus 100 according to an embodiment of the present invention. The testing apparatus 100 detects a modulated signal generated by an electronic device 200 by eliminating aliasing components from the modulated signal and tests the electronic device 200. The electronic device 200 is, for example, an SOC (System on Chip) which generates a modulated signal by modulating a predetermined signal which is modulated by a carrier signal having a predetermined frequency.

The testing apparatus 100 includes an AD converter 20, a detector 10, and an analyzing unit 50. The AD converter 20 makes the modulated signal, which the electric device 200 generates, discrete with a predetermined discrete frequency and generates a signal to be measured. It is desirable that the AD converter 20 makes the modulated signal discrete with a frequency twice or more of the Nyquist frequency of the modulated signal.

The detector 10 detects the signal to be measured generated by the AD converter 20. The detector 10 includes an analysis signal transfer 30, and base band signal generating unit 40. The analysis signal transformer 30 transforms the signal to be measured into a complex number analysis signal. By transforming the signal to be measured into the complex number analysis signal, it is possible to eliminate aliasing components of the signal to be measured which are generated due to the discreteness of the AD converter 20. Thus, it is possible to precisely detect the modulated signal. The real number part of the analysis signal is the signal to be measured, and the imaginary number part of the analysis signal is the signal generated by shifting the phase of all frequency components of the signal to be measured by 90 degree.

The base band signal generating unit 40 frequency-shifts the analysis signal and generates a complex base band signal of the signal to be measured. According to the present example, the base band signal generating unit 40 frequency-shifts the analysis signal based on the frequency of the carrier signal of the electronic device 200. The base band signal generating unit 40 may be a complex multiplier which frequency-shifts the analysis signal by multiplying the real number part and the imaginary number part by a complex number. In this case, the base band signal generating unit 40 multiplies the real number part and the imaginary number part by a complex number e^{-j2πfct}. Here, f_{c} shows the frequency of the carrier signal. The base band signal generating unit 40 generates I-phase signal and Q-phase signal which are phase-shifted real number part and imaginary number part of the analysis signal, respectively, and provide them with the analyzing unit 50.

According to the testing apparatus 100 of the present example, it is possible to eliminate aliasing components generated by the detection by the detector 10 because the base band signal generating unit 40 frequency-shifts the complex number analysis signal. Thus, it is possible to precisely detect the modulated signal.

The analyzing unit 50 decides acceptability of the electronic device 200 based on the I-phase signal and the Q-phase signal. For example, the analyzing unit 50 decides acceptability of the electronic device 200 based on the error vector magnitude (EVM) of the modulate signal. In other words, the analyzing unit 50 decides acceptability of the electronic device 200 by determining whether the modulated signal is properly modulated onto the IQ plane or not on the basis of the I-phase signal and the Q-phase signal.

As described above, according to the testing apparatus 100 of the present example, it is possible to eliminate the aliasing components generated by the discreteness and detection of the modulated signal, and thus, it is possible to precisely detect the modulated signal. Thus, it is possible to precisely decide acceptability of the electric device 200.

Further, according to the testing apparatus 100 of the present example, even if the electronic device 200 generates a signal by amplitude-modulation, phase-modulation or frequency modulation, it is possible to execute the test of the electronic device 200, the detection of the modulated signal, and the like, because the signal to be measured is transformed into the analysis signal.

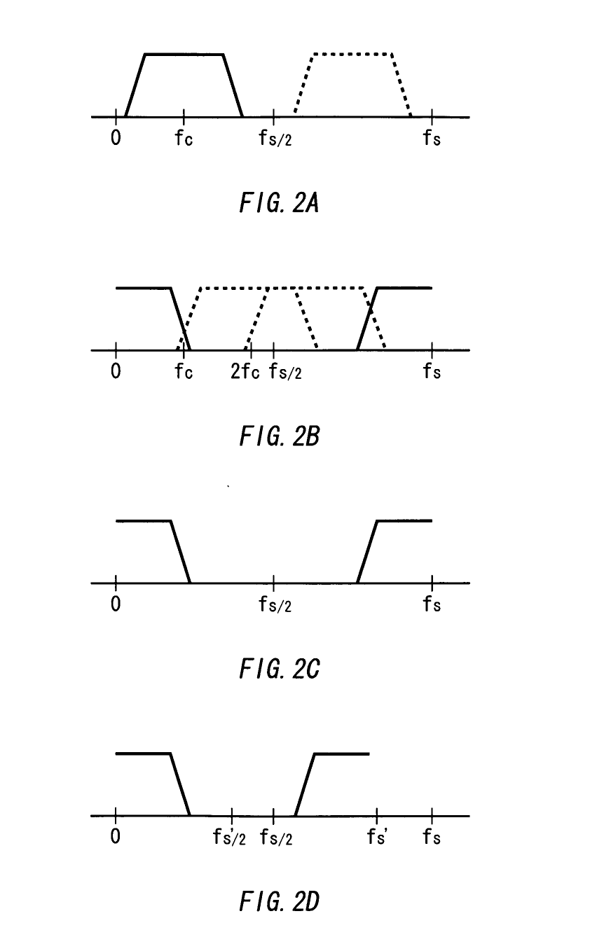

FIGS. 2A-2D shows examples of the frequency components of the signal to be detected. In FIGS. 2A-2D, fₛ describes the discrete frequency of the AD converter 20, and f_{c} describes the frequency of the carrier signal of the electronic device 200.

FIG. 2A shows an example of a frequency component of the signal to be detected which an AD converter 20 makes discrete. In case of making the signal discrete with a predetermined discrete frequency, for the actual frequency component described by the solid line in FIG. 2A, such an aliasing component as described by the broken line in FIG. 2A is generated with correspondent to the discrete frequency. The aliasing component is generated in the area symmetrical to the actual frequency component of the signal with respect to the fₛ/2.

By transforming the signal to be measured into the analysis signal, it is possible to eliminate negative frequency components. The aliasing component shown in FIG. 2A is a component which is generated with correspondent to the mirror component of the negative frequency area of the signal to be measured, and thus, the aliasing component can be eliminated by transforming the signal to be measured into the analysis signal. The testing apparatus 100 of the present example eliminates the aliasing component by transforming the signal to be measured into the analysis signal.

FIG. 2B shows an example of a frequency component in case of detecting an actual signal. In case that the signal has only real number components, if the actual signal for the base band signal generating unit 40 is frequency-shifted, the aliasing components described by the broken lines in FIG. 2B are generated. Further, in case of detecting the actual signal, the intensity of the frequency components finally becomes half of that of the frequency components of the actual signal before detecting. The testing apparatus 100 of the present example can eliminate the aliasing component because it transforms the signal to be measured into the analysis signal.

FIG. 2C shows an example of the frequency component of the signal detected by the testing apparatus 100 of the present example. As described above, the testing apparatus 100 can eliminate the aliasing components and thus detect the signal.

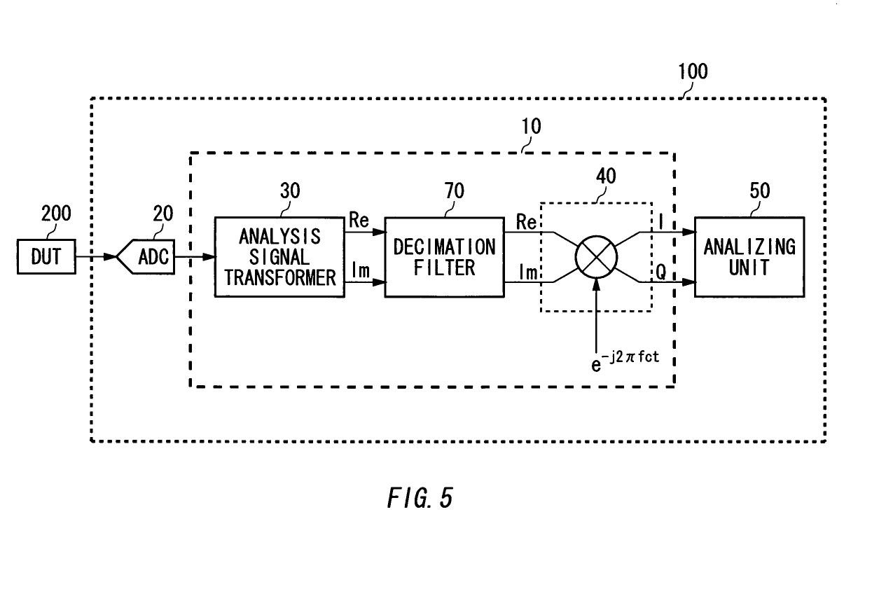

FIG. 2D shows an example of the frequency component of the signal detected by the testing apparatus 100 of the present example in case of down-sampling the analysis signal. The f′ₛ in FIG. 2D describes the discrete frequency of the analysis signal after down-sampling the analysis signal. For example, the testing apparatus 100 can also eliminate aliasing components and thus detect a signal in case of down-sampling the analysis signal by the decimation filter 70, which is described with regard to FIG. 5 as follows.

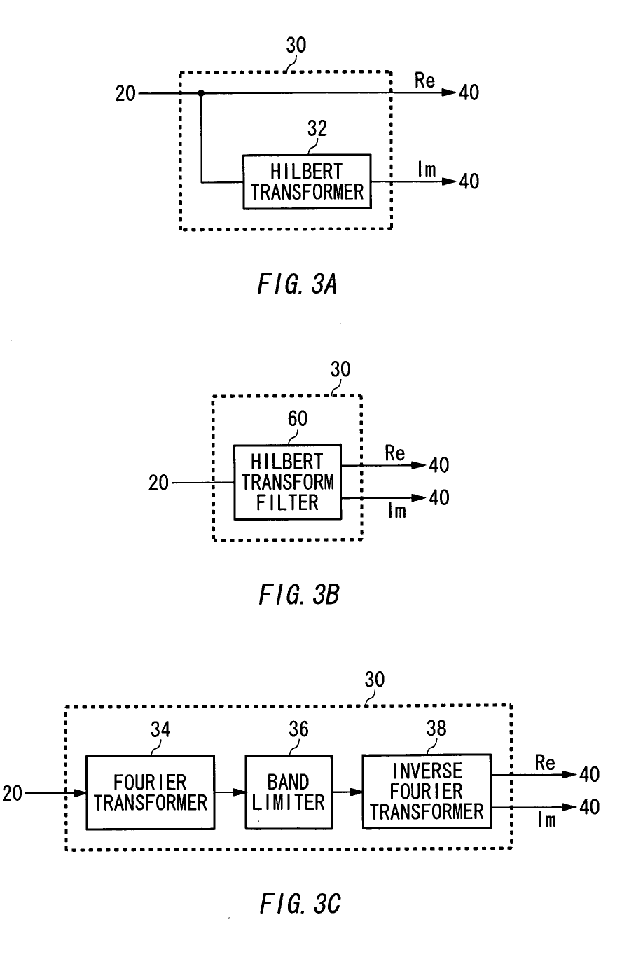

FIGS. 3A-3C show examples of the configuration of the analysis signal transformer 30. FIG. 3A shows an example of the configuration of the analysis signal transformer 30. The analysis signal transformer 30 of the present example includes a Hilbert transformer 32 which executes Hilbert transform of the signal to be measured. The analysis signal transformer 30 outputs the signal to be measured as a real number part of the analysis signal and outputs the signal to be measured which is Hilbert transformed by the Hilbert transformer 32 as an imaginary number part of the analysis signal. Thus, it is possible to generate the analysis signal which has the real number part and the imaginary number part having phase difference of 90 degree. The Hilbert transformer 32 may execute Hilbert transform by a software using, for example, DSP (Digital Signal Processor) or by hardware such as a Hilbert transform filter. By executing Hilbert transform of the modulated signal which is made to discrete by a digital circuit such as a Hilbert transform filter or computations, it is possible to generate the imaginary number part having phase difference of 90 degree with respect to the real number part precisely.

FIG. 3B shows another example of the configuration of the analysis signal transformer 30. In the present example, the analysis signal transformer 30 includes a Hilbert transform filter 60 which executes Hilbert transform of the signal to be measured and generates the discrete analysis signal. The configuration of the Hilbert transform filter 60 will be described later. As described above, the analysis signal transformer 30 of the present embodiment can generate the imaginary part having phase difference of 90 degree with respect to the real number part.

FIG. 3C shows another example of the configuration of the analysis signal transformer 30. In the present example, the analysis signal transformer 30 includes a Fourier transformer 34 which executes Fourier transform of the signal to be measured, a band limiter 36 which generates a band-limit signal by eliminating frequency components having frequency more than half of the discrete frequency for the AD converter 20 from the frequency components of the Fourier transformed signal to be measured, and an inverse Fourier transformer 38 which executes inverse Fourier transform of the band-limit signal and generates an analysis signal. The Fourier transformer 34 and inverse Fourier transformer 38 may execute fast Fourier transform and inverse fast Fourier transform, respectively.

The analysis signal can also be generated by the analysis signal transformer 30 of the present example in the same manner with the description regarding FIGS. 3A and 3B.

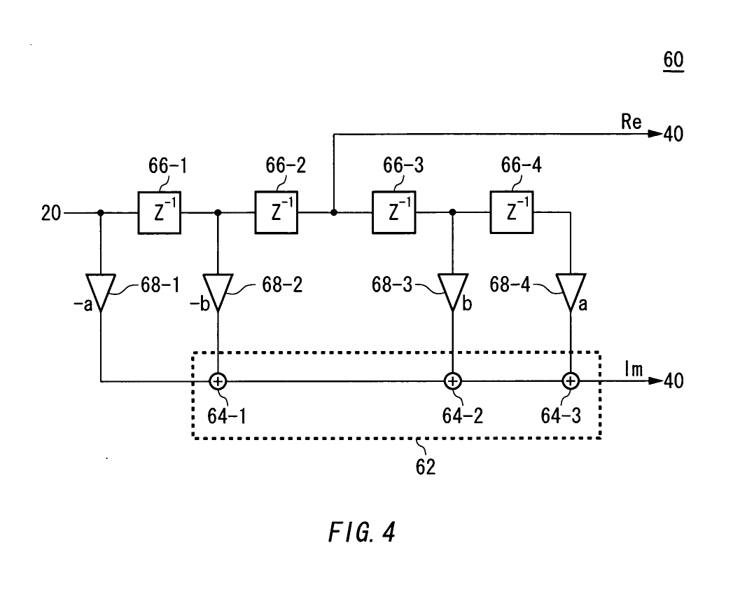

FIG. 4 shows an example of the configuration of the Hilbert transform filter 60. The Hilbert transform filter 60 includes a plurality of cascade-connected delay elements 66, a plurality of multipliers 68, and an adding unit 62.

The plurality of delay elements 66 receive the discrete data of the signal to be measured, each of which delays the data by a delay quantity corresponding to the discrete period of the signal to be measured and outputs the delayed data sequentially. The Hilbert transform filter 60 desirably has the even-number of delay elements and the plurality of multipliers 68 corresponding the delay elements.

Each of the multipliers 68 multiplies the data, which is input to the corresponding delay element 66 or is output form the corresponding delay element 66, by a predetermined coefficient. The multipliers 68 corresponding to the delay elements which in the first half, for example, 66-1 and 66-2, multiply the data which are input to the corresponding delay elements 66 by a predetermined coefficient, the multipliers 68 corresponding to the delay elements which in the second half, for example, 66-3 and 66-4, multiply the data which are output by the corresponding delay elements 66 by a predetermined coefficient. Further, as the predetermined coefficient, the multiplier 68 takes a coefficient corresponding to an impulse response function of a 90 degree phase-shift filter.

The adding unit 62 calculates the total sum of the values of multiplying the data output from the plurality of delay elements simultaneously by a predetermined coefficient using the plurality of multipliers. The Hilbert transform filter 60 sequentially outputs the data, which are sequentially output from the m-th delay element 66-M out of 2M delay elements 66 in cascade connection, as the real number part of the analysis signal, and outputs the values output from the adding unit 62 as the data of the imaginary number part corresponding to the data of the real number part.

Further, though the Hilbert transform filter 60 has four delay elements 66 in FIG. 4, the number of delay elements 66 is not limited to four. The Hilbert transform filter 60 may have two delay elements, and may generate the analysis signal more precisely by having more delay elements 66.

Furthermore, though the Hilbert transform filter 60 of the present example generates the imaginary number part of witch phase leads that of the real number part by 90 degree, the Hilbert transform filter may generate an imaginary number part of which phase lags that of the real number part by 90 degree in another example. In this case, the analysis signal may be generated by inverting the sign of each coefficient for the plurality of multipliers 68. In addition, the base band signal generating unit 40 inverts the sign of the frequency of the carrier signal to be multiplied, inverts the generated Q-phase component and provides the analyzing unit 50 with the inverted Q-phase component.

FIG. 5 shows another example of the configuration of the testing apparatus 100. The testing apparatus 100 in the present example further includes a decimation filter 70 in addition to the configuration of the testing apparatus 100 described in FIG. 1.

The decimation filter 70 extracts the complex data at every predetermined data number from the discrete complex data of the analysis signal generated by the analysis signal transformer 30, and provides the base band signal generating unit 40 with the complex data. Accordingly, the decimation filter 70 lowers the discrete frequency of the analysis signal and provides the base band signal generating unit 40 with the analysis signal. By lowering the discrete frequency of the analysis signal, the quantity of computation of the base band signal generating unit 40 can be reduced and a signal to be measured can be detected at a high-speed.

In FIG. 5, the decimation filter 70 is placed between the analysis signal transformer 30 and the base band signal generating unit 40. However, in another example, the decimation filter may be placed between the base band signal generating unit 40 and the analyzing unit 50, or the analysis signal transformer 30 may include the decimation filter. In case that the decimation filter 70 is placed between the analysis signal transformer 30 and the base band signal generating unit, the quantity of computation of the analyzing unit 50 can be reduced. Moreover, in this case, the decimation filter 70 may correct the gain of the complex base band signal generated by the base band signal generating unit 40.

In case that the decimation filter 70 corrects the gain of the complex base band signal, the correction value for correcting the gain of the complex base band signal is previously applied to the decimation filter 70. For example, either the amplitude value to be obtained by each complex data of the complex base band signal after correction or the value to be multiplied by each complex data may be given.

Further, the decimation filter 70 may correct the phase of the complex base band signal generated by the base band signal generating unit 40. It is desirable that the carrier signal's frequency of the electronic device 200 perfectly coincides with that of the complex number e^{-j2πfct} which is multiplied for the base band signal generating unit 40, however, there are some cases that an error between these frequencies is caused. The decimation filter 70 corrects the phase error of the complex base band signal caused by the error.

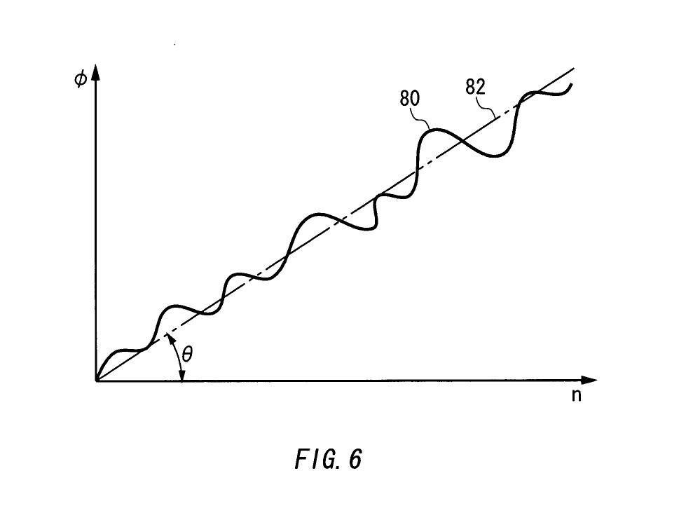

FIG. 6 is a drawing which explains the phase error correction of a complex base band signal for the decimation filter 70. First, the decimation filter 70 calculates the ratio of I-phase component to Q-phase component of the complex base band signal and arc tangent of the calculated ratio.

Since the testing apparatus 100 in the present example transforms a signal to be measured into an analysis signal, a phase error between the carrier signal of the electronic device 200 and that of the base band signal generating unit 40 can be calculated from arctangent of the ratio of an I-phase component to a Q-phase component of the complex base band signal so that the frequency error can be calculated from the phase error.

Since the calculated arc tangent of the ratio of the I-phase component to the Q-phase component is a periodic function related to a discrete time, the decimation filter 70 unwraps the periodic function and linear-approximates the unwrapped periodic function. FIG. 6 shows an arc tangent waveform 80 and a linear approximate waveform 82. In FIG. 6, the axis of abscissa shows the discrete time and the axis of ordinate shows the arc tangent value. In case that the carrier signal's frequency of the electronic device 200 perfectly coincides with that of the base band signal generating unit 40, the inclination of the linear approximate waveform from the axis of abscissa becomes zero. However, in case that an error is caused between the carrier signal's frequency of the electronic device 200 and that of the base band signal generating unit 40, the linear approximate waveform 82 has an inclination from the axis of abscissa as in FIG. 6.

An error between the carrier signal's frequency of the electronic device 200 and that of the base band signal generating unit 40 can be calculated from the inclination. The decimation filter 70 corrects the phases of the I-phase component and the Q-phase component, respectively, in order that the inclination becomes zero. Moreover, the carrier signal's frequency of the electronic device 200 and that of the base band signal generating unit can be the same by means of correcting a carrier signal's frequency f_{c} of the complex number e^{-j2πfct} in order that the phase error of the carrier signal is constant, for example, zero. According to the testing apparatus 100 in the present example, the phase error of the complex base band signal which is caused by the error between the carrier signal's frequency of the electronic device 200 and that of the base band signal generating unit 40, can be easily corrected. For this reason, the electronic device 200 can be tested precisely.

Further, in the above-mentioned example, the decimation filter 70 corrects the phase error of the complex base band signal due to the frequency error of the carrier signal, but, in another example, a correcting unit for correcting the phase error may be placed between the base band signal generating unit 40 and the analyzing unit 50.

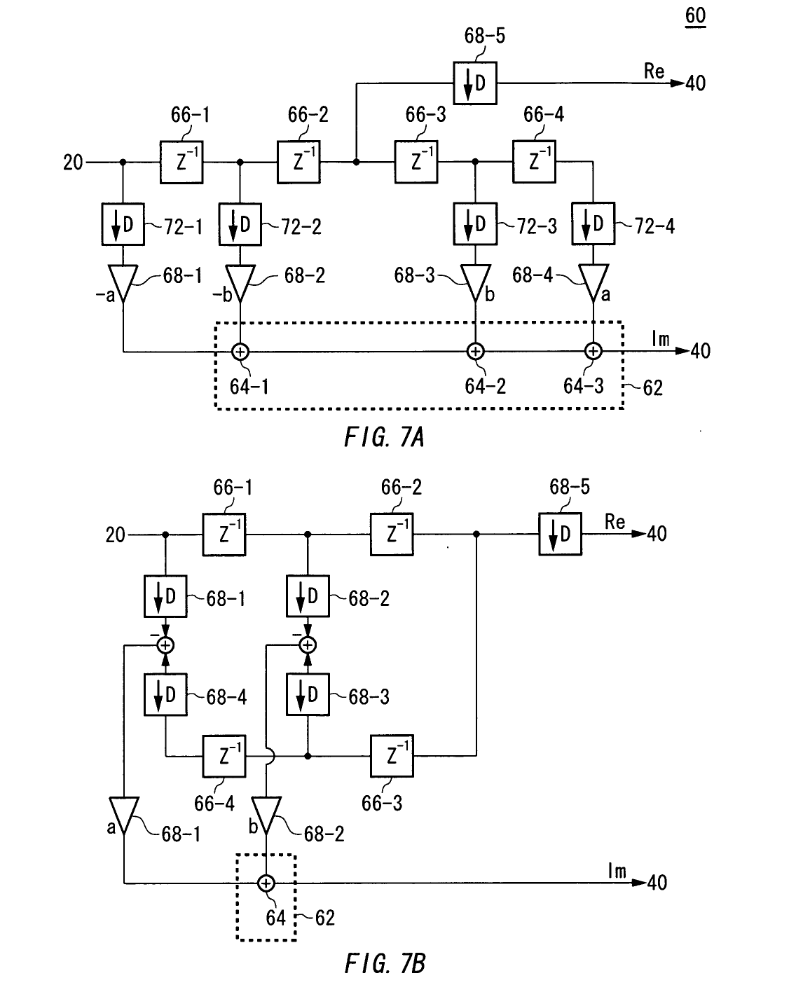

Furthermore, though the testing apparatus 100 described in FIG. 5 includes the decimation filter 70, in another example, the Hilbert transform filter 60 may function as the decimation filter 70. Accordingly, the Hilbert transform filter 60 may generate analysis signal of which the discrete frequency is lower than that of the signal to be measured. The Hilbert transform filter 60 in this case is described in FIG. 7.

FIGS. 7A and 7B show examples of the configuration of the Hilbert transform filter 60.

FIG. 7A shows another example of the configuration of the Hilbert transform filter 60. The Hilbert transform filter 60 in the present example further includes a plurality of the decimation filters 72 in addition to the configuration of the Hilbert transform filter 60 described in FIG. 4.

The plurality of the decimation filters 72 are placed corresponding to the delay element 66. The decimation filters 72 corresponding to the delay elements 66 in the first half of the plurality of cascade-connected delay elements 66 receive the data of the signal to be measured which are input into the delay elements 66, extract the data at every predetermined data number, and provide the corresponding multiplier 68 with the data. An adding unit 62 calculates the total sum of the data output from the decimation filters 72 synchronously. Moreover, the decimation filters 72 corresponding to the delay elements 66 in the second half receive the data of the signal to be measured output from the delay element 66, extract the data at every predetermined data number, and provide the corresponding multiplier 68 with the data.

In addition, the decimation filter 68-5 extracts the data of the real number part of the analysis signal at every predetermined data number and outputs the data. According to the Hilbert transform filter 60 in the present example, it is possible to reduce the quantity of computation of the multiplier 68 and the adding unit 62, and to generate the analysis signal at a high-speed.

FIG. 7B shows another example of the configuration of the Hilbert transform filter 60. The Hilbert transform filter 60 in the present example further includes the plurality of the decimation filters 72, which are placed with correspondent to the delay elements 66, and an adding unit 76, in addition to the configuration of the Hilbert transform filter 60 described in FIG. 4.

The plurality of the decimation filters 72 are placed with correspondent to the delay elements 66 and the multipliers 68 in the same manner with FIG. 7A. In the present example, two decimation filters 72, which have the same absolute value of the coefficients, correspond to one of the multipliers and the adding unit 76 calculates the sum of the extracted data for every two corresponding decimation filters 72. The adding unit 76 includes adders 74 which are placed with correspondent to every two decimation filters 72. Each adder 74 inverts the sign of the data received from the decimation filter 72 at the upstream and adds them.

Each of the multipliers 68 multiples the value, which is calculated by the corresponding adder 74 calculates, by the predetermined coefficient and the adding unit 62 calculates the total sum of the outputs from the multipliers 68. According to the Hilbert transform filter 60 in the present example, the same function can be performed with a small circuit size compared with the Hilbert transform filter 60 described in FIG. 7A.

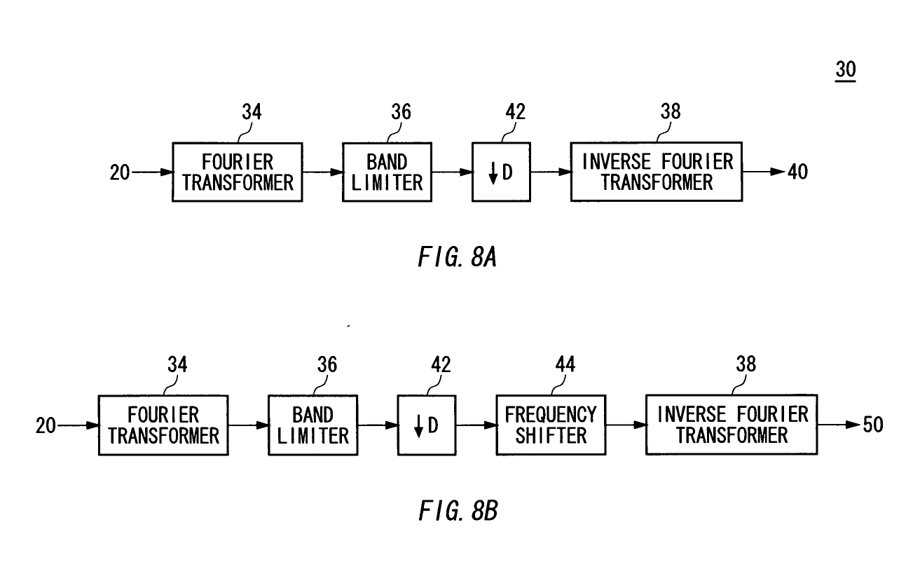

FIGS. 8A and 8B show examples of the configuration of an analysis signal transformer 30. FIG. 8A shows another example of the configuration of the analysis signal transformer 30 using Fourier transform. The analysis signal transformer 30 in the present example further includes a decimation filter 42 in addition to the configuration of the analysis signal transformer 30 described in FIG. 3C. The decimation filter 42 extracts the band-limit signal at every predetermined data number and outputs them. In the present example, the Fourier transformer 34 transforms the signal to be measured by discrete Fourier transform, and the decimation filter 42 down-samples the band-limit signal and outputs it. Accordingly, an inverse Fourier transformer 38 performs an inverse Fourier transform of the down-sampled band-limit signal and generates the analysis signal. According to this configuration, the amount of computation of the inverse Fourier transformer 38 can be reduced.

FIG. 8B shows another example of the configuration of the analysis signal transformer 30. The analysis signal transformer 30 in the present example further includes a frequency shifter 44 in addition to the configuration of the analysis signal transformer 30 described in FIG. 8A. The frequency shifter 44 shifts the band-limit signal output by the decimation filter 42 on a frequency axis based on the frequency of the carrier signal for the signal to be measured. Then, the inverse Fourier transformer 38 performs the inverse Fourier transform of the frequency-shifted band-limit signal so that it can detect the signal to be measured. Moreover, since the detector 100 in the present example can detect the signal to be measured at the analysis signal transformer 30, it is not required to include a base band generating unit.

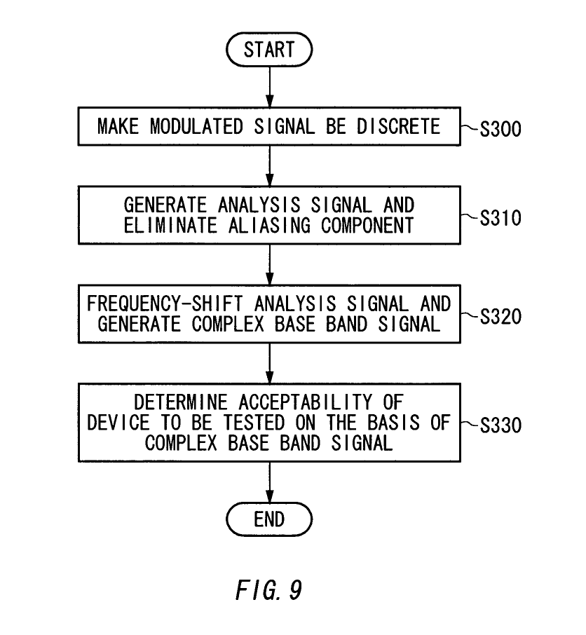

FIG. 9 is a flowchart to explain an example of a testing method according to an embodiment of the present invention. The testing method in the present example is performed by means of the testing apparatus 100. First, in an AD converting step S300, an AD converter 20 makes a modulated signal discrete and transforms it into a signal to be measured. Next, in an analysis signal transforming step S310, the analysis signal transformer 30 transforms the signal to be measured into an analysis signal of which the discrete frequency is lower than that of the signal to be measured so that it eliminates aliasing components of the signal to be measured due to the discreteness.

Next, in a base band signal generating step S320, the base band signal generating unit 40 frequency-shifts the analysis signal and generates a complex base band signal of the signal to be measured. Finally, in an analyzing step S330, the analyzing unit 50 determines acceptability of the electronic device 200 on the basis of the complex base band signal. In each step explained in the present example, the detailed function of the testing apparatus 100 is the same as that explained with reference to FIG. 1 to FIG. 8. According to the testing method in the present example, in the same manner with the testing apparatus 100, the electronic device 200 can be tested precisely.

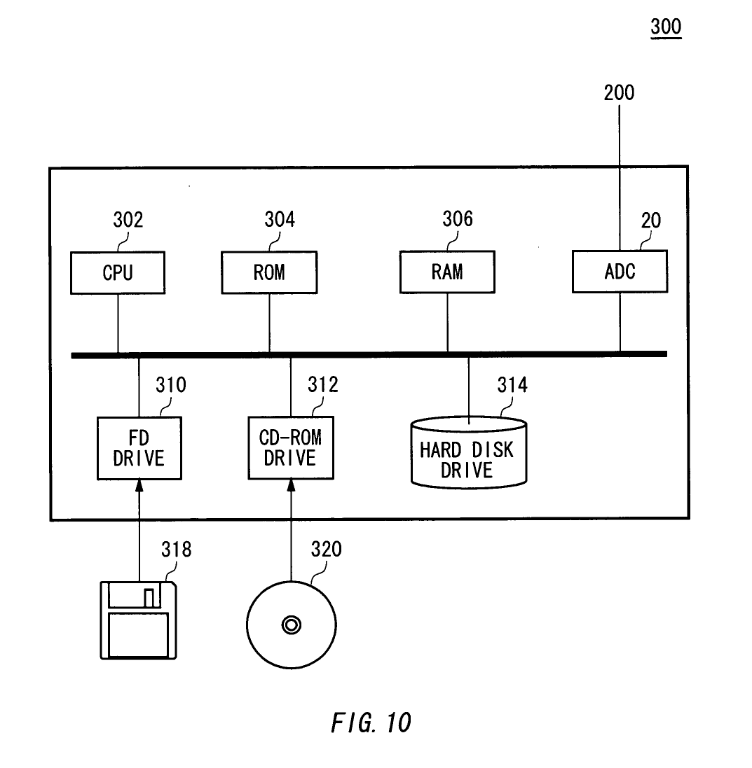

FIG. 10 shows an example of the hardware configuration of a computer 300 according to an embodiment of the present invention. The computer 300 includes a CPU 302, ROM 304, RAM 306, a communication interface 308, a hard disk drive 314, a database interface 316, a floppy disk drive 310, a CD-ROM drive 312 and an AD converter 20. The CPU 302 functions on the basis of the program stored on the ROM 304, the RAM 306, or the hard disk drive 314 and controls each part. Moreover, the CPU 302 may control each part on the basis of the program read by the floppy disk drive 310 or the CD-ROM drive 312 from the floppy disk 318 or the CD-ROM 320. The program stored on these recording mediums may be compressed or not.

The program stores a program which makes the computer 300 perform functions as the testing apparatus 100 explained in FIG. 1 to FIG. 8. For example, the program makes the computer 300 function as the AD converter 20 to make the modulated signal discrete and transform it into a signal to be measured, as the analysis signal transformer 30 to eliminate aliasing components of the signal to be measured due to the discreteness by transforming the signal to be measured into the analysis signal of which the discrete frequency is lower than that of the signal to be measured, as a base band signal generating unit 40 to frequency-shift the analysis signal and generate a complex base band signal of the signal to be measured and as an analyzing unit 50 to determine acceptability of the electronic device 200 on the basis of the complex base band signal. In this case, the program makes the CPU 302 perform functions as the analysis signal transformer 30, the base band signal generating unit 40 and the analyzing unit 50. Moreover, the RAM 306 may store a computation process and a computation result.

In addition, the computer 300 may function as an apparatus to realize a part of function of the testing apparatus 100 explained with reference to FIG. 1 to FIG. 8B. Moreover, the program may be stored on either one or a plurality of recoding mediums.

An optical recoding medium such as DVD, PD, etc., a magneto-optical recording medium such as MD, a tape medium, a magnetic recoding medium, a semiconductor memory such as an IC card, and a miniature card can be used as a recoding medium in addition to a floppy disk and a CD-DOM.

As obvious from the description above, according to the detector related to the present invention, it is possible to detect the signal to be measured precisely. For this reason, it is possible to test the electronic device precisely.

Although the present invention has been described by way of exemplary embodiments, it should be understood that those skilled in the art might make many changes and substitutions without departing from the spirit and the scope of the present invention, which is defined only by the appended claims.

1. A detector for detecting a signal to be measured, which is made to discrete with a predetermined discrete frequency, comprising:
an analysis signal transformer for eliminating aliasing components of the signal to be measured, which are generated due to the discreteness, by transforming the signal to be measured into an analysis signal of which the discrete frequency is lower than that of the signal to be measured; and
a base band signal generating unit for frequency-shifting the analysis signal and generating a complex base band signal of the signal to be measured.

2. A detector as claimed in claim 1, wherein said analysis signal transformer comprises a decimation filter, which extracts complex data from discrete complex data of the analysis signal at every predetermined data number and provides said base band signal generating unit with the extracted complex data.

3. A detector as claimed in claim 1, wherein said analysis signal transformer outputs the signal to be measured as a real number part of the analysis signal and outputs the Hilbert transformed signal of the signal to be measured as an imaginary number part of the analysis signal.

4. A detector as claimed in claim 3, wherein said analysis signal transformer generates the analysis signal which is made to discrete by a Hilbert transform filter.

5. A detector as claimed in claim 3, wherein said analysis signal transformer comprises a Hilbert transform filter for generating the analysis signal which is made to discrete,
said Hilbert transform filter comprises:
a plurality of cascade-connected delay elements which receive the discrete data of the signal to be measured, each of which delays the data by a delay quantity corresponding to the discrete period of the signal to be measured and outputs the delayed data sequentially;
a plurality of decimation filters for extracting data from the data which are output from said plurality of delay elements at every predetermined data number;
a plurality of multipliers, each of which multiplies the extracted data from each of said plurality of decimation filters by a predetermined coefficient; and
an adding unit for calculating a total sum of the data which are synchronously output from said decimation filters and multiplied by the predetermined coefficient by said plurality of multipliers and generating an imaginary number part of the analysis signal.

6. A detector as claimed in claim 3, wherein said analysis signal transformer comprises a Hilbert transform filter for generating the analysis signal which is made to discrete,
said Hilbert transform filter comprises:
a plurality of cascade-connected delay elements which receive the discrete data of the signal to be measured, each of which delays the data by a delay quantity corresponding to the discrete period of the signal to be measured and outputs the delayed data sequentially;
a plurality of decimation filters for extracting data from the data which are output from said plurality of delay elements at every predetermined data number;
an adding unit for calculating a sum of the extracted data for every two corresponding decimation filters;
a multiplying unit for multiplying each of the sums of the data which are calculated by said adding unit by a predetermined coefficient; and
an adder for calculating a total sum of the data which are synchronously output from said decimation filters and multiplied by the predetermined coefficient by said multiplying unit.

7. A detector as claimed in claim 1, wherein said analysis signal transformer comprises:
a Fourier transforming unit for applying discrete Fourier transform to the signal to be measured;
a band limiter for generating a band-limit signal by eliminating frequency components of which the frequency is higher than about half of the discrete frequency from the frequency components of the signal to be measured which is discrete Fourier transformed; and
an inverse Fourier transforming unit for generating the analysis signal by applying inverse Fourier transform to the band-limit signal.

8. A detector as claimed in claim 7, wherein said analysis signal transformer further comprises a decimation filter which extracts complex data of the discrete base-limit signal at every predetermined data number and provides said inverse Fourier transforming unit with the extracted complex data.

9. A detector as claimed in claim 1, wherein
the signal to be measured is a signal which is frequency-shifted by a carrier signal having a predetermined frequency,
said base band signal generating unit phase-shifts the frequency of the analysis signal on the basis of the predetermined frequency.

10. A detector for detecting a signal to be measured, which is made to discrete with a predetermined discrete frequency, comprising:
an analysis signal transformer for eliminating aliasing components of the signal to be measured, which are generated due to the discreteness, by transforming the signal to be measured into an analysis signal;
a base band signal generating unit for frequency-shifting the analysis signal and generating a complex base band signal of the signal to be measured; and
a decimation filter for receiving the complex base band signal, extracting the complex data from the complex data of the complex base band signal at every predetermined data number, and generating the complex base band signal of which the discrete frequency is lower than that of the signal to be measured.

11. A detector as claimed in claim 10, wherein said decimation filter corrects the value of the amplitude of each complex data of the complex base band signal on the basis of a predetermined value.

12. A detector as claimed in claim 11, wherein said decimation filter corrects the phase of the complex base band signal on the basis of the ratio of I-phase component to Q-phase component of the complex base band signal.

13. A detector for detecting a signal to be measured, which is made to discrete with a predetermined discrete frequency and frequency-shifted by a carrier signal having a predetermined frequency, comprising:
a Fourier transforming unit for applying Fourier transform to the signal to be measured;
a band limiter for generating a band-limit signal by eliminating frequency components of which the frequency is higher than about half of the discrete frequency from the frequency components of the signal to be measured which is Fourier transformed;
a decimation filter for extracting and outputting the band-limit signal at every predetermined data number;
a frequency-shifter for shifting the band-limit signal, which said decimation filter outputs, on a frequency axis on the basis of the carrier signal; and
an inverse Fourier transforming unit for applying inverse Fourier transform to the band-limit signal which is frequency-shifted by said frequency shifter.

14. A testing apparatus, which decides acceptability of an electronic device on the basis of a modulated signal output from the electronic device, comprising:
an AD converter for making the modulated signal discrete and converting into a signal to be measured;
an analysis signal transformer for eliminating aliasing components of the signal to be measured, which are generated due to the discreteness, by transforming the signal to be measured into an analysis signal of which the discrete frequency is lower than that of the signal to be measured;
a base band signal generating unit for phase-shifting the analysis signal and generating a complex base band signal of the signal to be measure; and
an analyzing unit for deciding acceptability of the electronic device based on the complex base band signal.

15. A testing method which decides acceptability of an electronic device on the basis of a modulated signal output from the electronic device, comprising:
an AD converting step of making the modulated signal discrete and converting into a signal to be measured;
an analysis signal transforming step of eliminating aliasing components of the signal to be measured, which are generated due to the discreteness, by transforming the signal to be measured into an analysis signal of which the discrete frequency is lower than that of the signal to be measured;
a base band signal generating step of phase-shifting the analysis signal and generating a complex base band signal of the signal to be measure; and
an analyzing step of deciding acceptability of the electronic device based on the complex base band signal.

16. A machine readable medium storing thereon a program for making a computer perform functions as a testing apparatus, which decides acceptability of an electronic device on the basis of a modulated signal output from the electronic device, wherein said program makes said computer perform functions as:
an AD converter for making the modulated signal discrete and converting into a signal to be measured;
an analysis signal transformer for eliminating aliasing components of the signal to be measured, which are generated due to the discreteness, by transforming the signal to be measured into an analysis signal of which the discrete frequency is lower than that of the signal to be measured;
a base band signal generating unit for phase-shifting the analysis signal and generating a complex base band signal of the signal to be measure; and
an analyzing unit for deciding acceptability of the electronic device based on the complex base band signal.
